(19) United States
(12) Patent Application Publication
(10) Pub. No.: US 2024/0429119 A1
(43) Pub. Date: Dec. 26, 2024

(54) SEMICONDUCTOR APPARATUS

(71) Applicant: FUJI ELECTRIC CO., LTD., Kanagawa (JP)

(72) Inventor: Shigeki SATO, Azumino-city (JP)

(21) Appl. No.: 18/641,401

(22) Filed: Apr. 21, 2024

(30) Foreign Application Priority Data
Jun. 22, 2023 (JP) 2023-102284

(51) Int. Cl. H01L 23/31; H01L 23/00; H01L 23/495; H01L 29/739; H01L 29/861

(52) U.S. Cl. CPC H01L 23/3157; H01L 23/49562; H01L 24/32; H01L 29/7393; H01L 29/861; H01L 2224/32245

(57) ABSTRACT

Provided is a semiconductor apparatus, comprising: a first electrode arranged above the semiconductor substrate; a protective film having a portion provided above the first electrode; a solder portion arranged sandwiching the protective film in a first direction parallel to an upper surface of the first electrode, a leadframe fixed by the solder portion and arranged above the protective film; and a second electrode, wherein when a width of the protective film is denoted as W1, a length of the protective film is denoted as L1, an arithmetic average roughness of a surface of the protective film is denoted as Ra, a scatter index is denoted as I, and a distance between the protective film and the second electrode is denoted as Dmin, following equations are satisfied: I=((Ra/4)×L1)/(2×(W1×W1/π)^{0.5}), Dmin>2.583×I−16599.

The contents of the following patent application(s) are incorporated herein by reference: NO. 2023-102284 filed in JP on Jun. 22, 2023

### BACKGROUND

### 1. Technical Field

The present invention relates to a semiconductor apparatus.

### 2. Related Art

Conventionally, in a semiconductor apparatus, a structure provided with a protective film of polyimide or the like is known (for example, see Patent Document 1 to 4).
Patent Document 1: Japanese Patent Application Publication No. 2022-168905
Patent Document 2: Japanese Patent Application Publication No. 2007-158113
Patent Document 3: Japanese Patent Application Publication No. H4-155852
Patent Document 4: Japanese Patent Application Publication No. 2018-074068

### BRIEF DESCRIPTION OF THE DRAWINGS

FIG. 1 shows a top view showing an example of a semiconductor apparatus 100 according to one embodiment of the present invention.

FIG. 2 shows an arrangement example of a gate runner 48 in a semiconductor substrate 10.

FIG. 3 shows an arrangement example of a protective film 150 provided above an upper surface of the semiconductor substrate 10.

FIG. 4 shows an example of an A-A cross section in FIG. 3.

FIG. 5 shows an arrangement example of the protective film 150-1 and a solder tunnel 170 in a top view.

FIG. 6 shows a measurement result of a relationship between a scatter index I and an excessive portion 162.

FIG. 7 shows an arrangement example of an end 175 of the protective film 150-1 and a second electrode 50.

FIG. 8 shows another example of the A-A cross section.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solution of the invention.

In the present specification, one side in a direction parallel to a depth direction of a semiconductor substrate is referred to as “upper” and another side is referred to as “lower”. One surface of two principal surfaces of a substrate, a layer or other member is referred to as an upper surface, and another surface is referred to as a lower surface. “Upper” and “lower” directions are not limited to a gravitational direction or to a direction in which a semiconductor apparatus is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. It should be noted that a +Z axis direction and a −Z axis direction are directions opposite to each other. When the Z axis direction is described without describing the signs, it means that the direction is parallel to the +Z axis and the −Z axis. Further, in the present specification, a case of viewing from the +Z axis direction may be referred to as a top plan view.

In the present specification, a case where a term such as “same” or “equal” is mentioned may also include a case where there is an error due to a variation in manufacturing or the like. The error is, for example, within 10%.

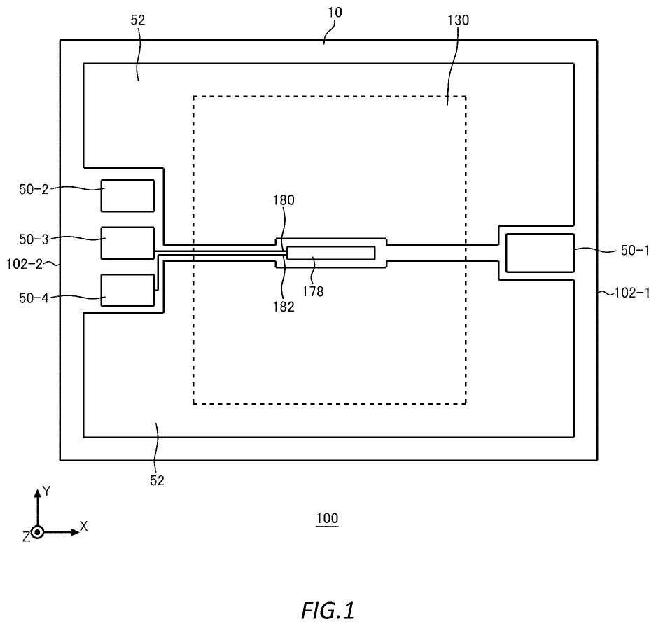

FIG. 1 shows a top view showing an example of a semiconductor apparatus 100 according to one embodiment of the present invention. The semiconductor apparatus 100 comprises a semiconductor substrate 10. The semiconductor substrate 10 is a substrate formed of a semiconductor material such as silicon or a compound semiconductor. The semiconductor substrate 10 has an end side 102 in a top view. The semiconductor substrate 10 in the present example has two sets of end sides 102 facing each other in a top view. FIG. 1 shows one set of a first end side 102-1 and a second end side 102-2 facing each other. In FIG. 1, a direction that is parallel to the first end side 102-1 and the second end side 102-2 is denoted as a Y axis direction, and a direction that is perpendicular to the first end side 102-1 and the second end side 102-2 is denoted as a X axis direction.

The semiconductor substrate 10 is provided with a semiconductor device such as an IGBT (insulated gate bipolar transistor). The semiconductor substrate 10 may be further provided with a free wheeling diode which is connected in inverse parallel to the IGBT and through which current flows when the IGBT transitions from an ON state to an OFF state.

The semiconductor apparatus 100 may be a vertical device which is provided with a main electrode (for example, an emitter electrode and a collector electrode) on each of an upper surface and a lower surface of the semiconductor substrate 10, and in which a main current (for example, a collector current) flows between the upper surface and the lower surface, or may be a horizontal device provided with two main electrodes on the upper surface of the semiconductor substrate 10 and in which the main current flows in a direction parallel to the upper surface. The semiconductor apparatus 100 may have a structure in which a gate electrode is embedded in a trench formed on the upper surface of the semiconductor substrate 10, or may have a structure in which the gate electrode is arranged above the upper surface of the semiconductor substrate 10.

The semiconductor apparatus 100 includes one or more first electrodes 52, one or more second electrodes 50, and a leadframe 130. For example, the first electrode 52 is an emitter electrode of the IGBT. The first electrode 52 is arranged above the upper surface of the semiconductor substrate 10. An interlayer dielectric film is provided between the first electrode 52 and the semiconductor substrate 10. The first electrode 52 is connected to the semiconductor substrate 10 via a contact hole provided in the interlayer dielectric film.

The semiconductor apparatus 100 has one or more second electrodes 50. The second electrodes 50 are electrodes other than the first electrode 52 among the electrodes arranged above the upper surface of the semiconductor substrate 10. For example, the second electrodes 50 are a gate pad of the IGBT, a pad for current detection, and a pad for temperature detection. In the example of FIG. 1, the second electrode 50-1 is the gate pad, the second electrode 50-2 is the pad for current detection, and the second electrode 50-3 and the second electrode 50-4 are the pads for temperature detection. The first electrode 52 and the second electrode 50 are formed of a metal material such as aluminum.

Gate voltage for switching the IGBT or the like is applied to the second electrode 50-1 of the present example. The second electrode 50-1 is connected to an external circuit through wiring such as a wire. The second electrode 50-1 is connected to the gate electrode of the IGBT or the like through wiring such as a gate runner.

A device for current detection is provided on the semiconductor substrate 10 below the second electrode 50-2 of the present example. The device for current detection is the IGBT, for example. The second electrode 50-2 may be an emitter electrode of the IGBT for current detection. The second electrode 50-2 is connected to an external circuit through wiring such as a wire.

The second electrode 50-3 and the second electrode 50-4 of the present example are connected to a temperature detecting element 178 through wiring 180 and wiring 182. The temperature detecting element 178 is, for example, a PN junction diode provided above the semiconductor substrate 10. The wiring 180 and the wiring 182 are, for example, provided above the semiconductor substrate 10. Since the PN junction diode has a thermal property, the temperature of the semiconductor apparatus 100 can be detected by detecting an electrical property of the PN junction diode. One electrode of the second electrode 50-3 or the second electrode 50-4 is connected to a cathode of the PN junction diode, and another electrode is connected to an anode of the PN junction diode. The second electrode 50-3 and the second electrode 50-4 are connected to an external circuit through wiring such as a wire.

The leadframe 130 is metal wiring connected to the first electrode 52. The leadframe 130 may have a plate-like portion to be connected to the first electrode 52. The leadframe 130 and the first electrode 52 are connected by a solder portion.

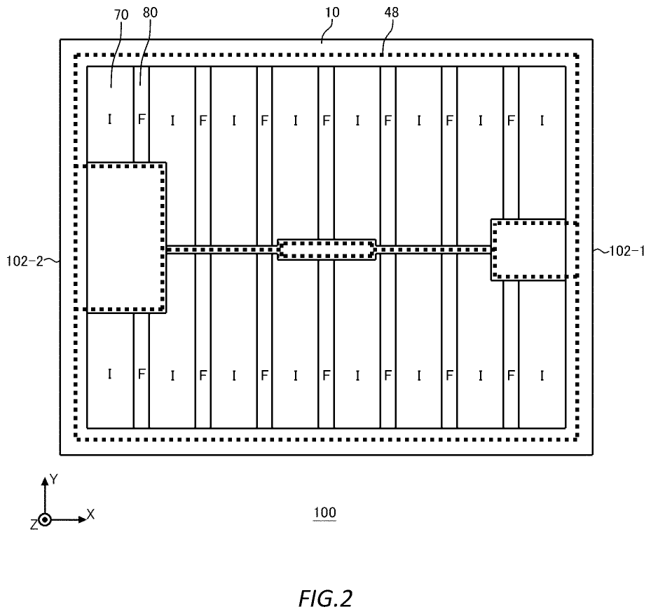

FIG. 2 shows an arrangement example of a gate runner 48 in the semiconductor substrate 10. A transistor portion 70 and a diode portion 80 are provided on the semiconductor substrate 10 of the present example. The transistor portion 70 is an IGBT, for example. The diode portion 80 is a free wheeling diode, for example. In FIG. 2, a region provided with the transistor portion 70 is marked by the sign I, and a region provided with the diode portion 80 is marked by the sign F. The transistor portion 70 and the diode portion 80 may be arranged alternately along the X axis direction.

The gate runner 48 connects the second electrode 50-1 shown in FIG. 1 to a gate electrode of each transistor portion 70. The gate runner 48 may be provided between an end side 102 of the semiconductor substrate 10 and the transistor portion 70 and the diode portion 80. The gate runner 48 may be circularly provided along the end side 102 of the semiconductor substrate 10. The gate runner 48 may be provided so as to surround the circumference of the first electrode 52 and the second electrode 50. In addition, when two transistor portions 70 are separately provided in the Y axis direction as shown in FIG. 2, the gate runner 48 may also be provided between the two transistor portions 70. In the example of FIG. 2, the gate runner 48 is provided along the temperature detecting element 178, the wiring 180, and the wiring 182 shown in FIG. 1.

The gate runner 48 may be metal wiring formed of a metal material such as aluminum, may be semiconductor wiring formed of impurity-added polysilicon or the like, or may be stacked wiring in which the metal wiring and the semiconductor wiring are stacked. By providing the gate runner 48, magnitude and application timing of the gate voltage on each transistor portion 70 can be equalized.

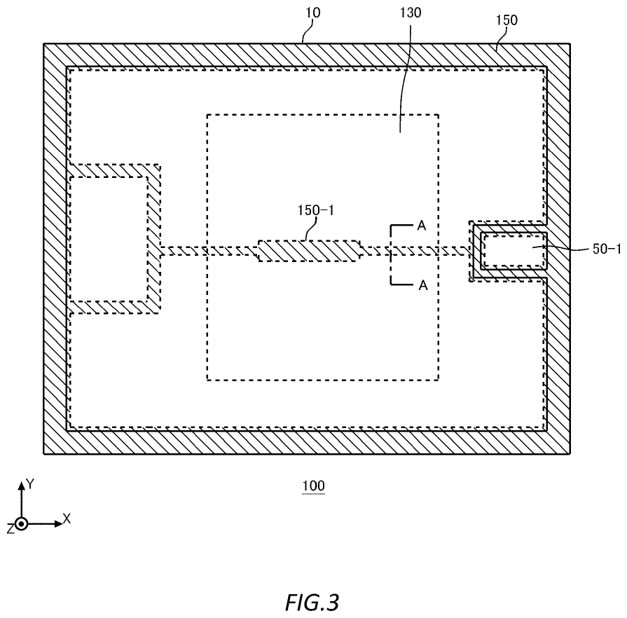

FIG. 3 shows an arrangement example of a protective film 150 provided above an upper surface of the semiconductor substrate 10. In FIG. 3, a region on which the protective film 150 is arranged is shown by hatching with diagonal lines. The protective film 150 is, for example, resin such as polyimide or the like. The protective film 150 includes a portion provided above the first electrode 52. At least a part of the protective film 150 is provided on a region in which the first electrode 52 and the second electrode 50 are not provided. A part of the protective film 150 may be provided on the upper surface of the first electrode 52 or the second electrode 50. The protective film 150 is provided so that at least part of each electrode of the first electrode 52 and the second electrode 50 is exposed. Each electrode of the first electrode 52 and the second electrode 50 is connected to wiring such as the leadframe 130 and the wire at the portion exposed from the protective film 150.

The protective film 150 of the present example is provided to cover the gate runner 48 from above. A part of the protective film 150 is provided below the leadframe 130. The protective film 150 below the leadframe 130 is denoted as a protective film 150-1. In the example of FIG. 3, a part of the protective film 150 that is arranged in line with respect to the second electrode 50-1 in the X axis direction is provided below the leadframe 130. A part of the protective film 150-1 may be provided above the temperature detecting element 178, the wiring 180, and the wiring 182. The leadframe 130 is provided in a wider range than the protective film 150 in the Y axis direction (first direction). The leadframe 130 may be provided in a narrower range than the protective film 150 in the X axis direction.

A part of the protective film 150 may be provided so as to surround the region in which the leadframe 130 is provided. With such a configuration, it is possible to inhibit the solder portion below the leadframe 130 from flowing outside the leadframe 130.

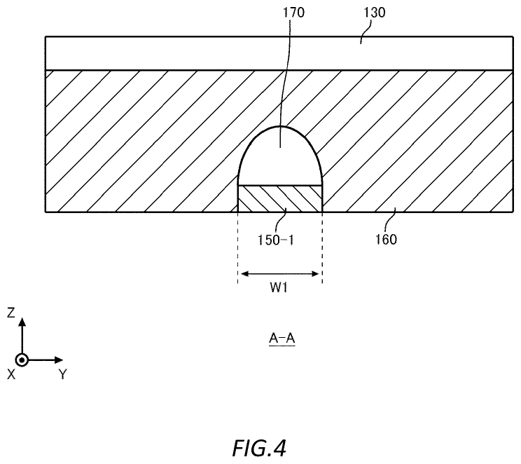

FIG. 4 shows an example of an A-A cross section in FIG. 3. The A-A cross section is a YZ plane that passes through the leadframe 130 and the protective film 150-1. In the A-A cross section in FIG. 4, the semiconductor substrate 10, the first electrode 52, and the like are omitted.

A solder portion 160 is provided below the leadframe 130. At least a part of the solder portion 160 is arranged in contact with the upper surface of the first electrode 52. The leadframe 130 is fixed to the first electrode 52 by the solder portion 160. The leadframe 130 is provided above the protective film 150-1.

As shown in FIG. 3, since the leadframe 130 is provided in a wider range than the protective film 150-1 in the Y axis direction, the protective film 150-1 is sandwiched between the solder portions 160 in the Y axis direction. The solder portion 160 may or may not have a portion that is provided at the same height as the protective film 150-1. The protective film 150-1 is sandwiched between the solder portions 160 in the Y axis direction at least in a top view.

The upper surface of the protective film 150-1 formed of resin such as polyimide has a relatively low solder wettability. Thus, even if the protective film 150-1 is arranged below the leadframe 130, the solder portion 160 may not be formed on the upper surface of the protective film 150-1. In the present specification, a space in which the solder portion 160 is not formed between the protective film 150-1 and the leadframe 130 is referred to as a solder tunnel 170. The solder tunnel 170 is surrounded by the protective film 150-1 and the solder portion 160 in the YZ cross section. The solder tunnel 170 may have a region where no solder portion 160 is provided on the top and may have a portion where a bottom surface of the leadframe 130 is exposed to the solder tunnel 170. The width of the protective film 150-1 in the Y axis direction is denoted as W1 (μm). The width of the solder tunnel 170 in the Y axis direction may also be W1. The width of the solder tunnel 170 may be the width of a space at the position where it contacts the upper surface of the protective film 150-1.

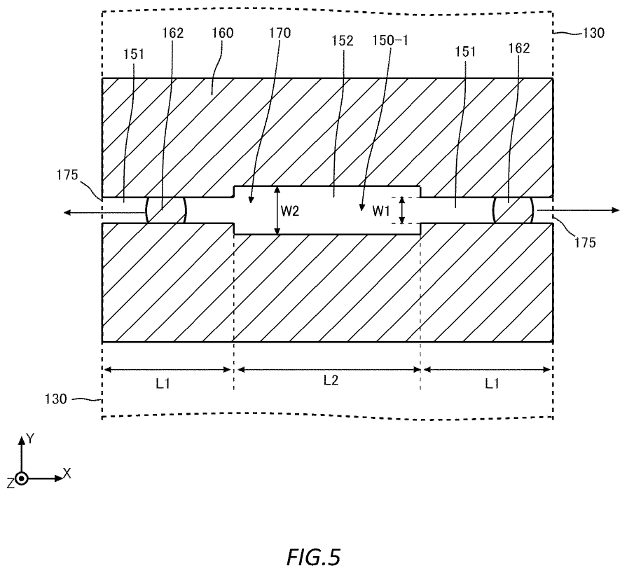

FIG. 5 shows an arrangement example of the protective film 150-1 and the solder tunnel 170 in a top view. In the present example, the protective film 150-1 is provided in the same region as the solder tunnel 170. In FIG. 5, the hatching of the protective film 150-1 is omitted.

As described in FIG. 3, the leadframe 130 is provided in a narrower range than the protective film 150 in the X axis direction. Thus, the protective film 150-1 is not sandwiched between the solder portions 160 in the X axis direction (second direction). That is, an end 175 of the solder tunnel 170 in the X axis direction is not covered by the solder portion 160 and is open. The end 175 also coincides with the end of the protective film 150-1. The second direction may be the same as the longitudinal direction of the protective film 150-1. The longitudinal direction of the protective film 150-1 refers to a direction in which the protective film 150-1 extends. The longitudinal direction of the protective film 150-1 may refer to a direction that is parallel to the longest side among the end sides of the protective film 150-1. The first direction described above may be a direction that is perpendicular to the second direction. As an example, the first direction is the Y axis direction and the second direction is the X axis direction.

At least one of the second electrodes 50 shown in FIG. 1 or the like is arranged on an outer side in the X axis direction relative to the end 175. The outer side in the X axis direction relative to the end 175 refers to a region from the end 175 to an end side 102 facing said end 175 in the X axis direction. In the example of FIG. 1, the second electrode 50-1 is arranged between the end 175 and the end side 102-1, and the second electrodes 50-2, 50-3, and 50-4 are arranged between the end 175 and the end side 102-2.

The upper surface of the protective film 150-1 has a low wettability to solder and thus the solder portion 160 is not easily formed inside the solder tunnel 170. However, in the manufacturing process of the semiconductor apparatus 100, some solder may enter the solder tunnel 170. For example, if the amount of solder in the solder portion 160 is too much, some solder may enter the solder tunnel 170. In the example of FIG. 5, an excessive portion 162 has entered the solder tunnel 170.

The manufacturing process of the semiconductor apparatus 100 of the present example includes a process for forming a vacuum in a space in which the semiconductor apparatus 100 is arranged. For example, vacuum reflow may be performed when the leadframe 130 is fixed by the solder portion 160. When the vacuum reflow is performed on the semiconductor apparatus 100, the air inside the solder tunnel 170 expands due to decompression and flows out of the solder tunnel 170. If the excessive portion 162 exists in the solder tunnel 170, the solder of the excessive portion 162 may be scattered to the outside of the solder tunnel 170. If the scattered solder adheres to the second electrode 50, it becomes difficult to bond the wiring such as a wire to the second electrode 50.

The semiconductor apparatus 100 of the present example inhibits adhesion of the solder to the second electrode 50 even if the solder is scattered from the inside of the solder tunnel 170. Accordingly, the manufacturing of the semiconductor apparatus 100 can be facilitated and the reliability of connections between the second electrode 50 and the wiring can be improved. As an example, by adjusting the structure of the solder tunnel 170, a flying distance of the solder scattering from the end 175 is controlled.

A width in the Y axis direction of the protective film 150-1 arranged below the leadframe 130 is denoted as W1 (μm), a length in the X axis direction of the protective film 150-1 is denoted as L1 (μm), and arithmetic average roughness of the surface of the protective film 150-1 is denoted as Ra (μm). The surface of the protective film 150-1 corresponds to the bottom surface of the solder tunnel 170.

The protective film 150-1 of the present example has the first portion 151 and the second portion 152. The first portion 151 is a portion that is provided to extend in the direction toward the second electrode 50 from the second portion 152 and that has a narrower width in the Y axis direction than the second portion 152. The direction toward the second electrode 50 refers to the direction in which a distance to the second electrode 50 decreases. The second electrode 50 may be arranged on a straight line extending from the first portion 151. The first portion 151 of the present example extends in the X axis direction. That is, the long side of the first portion 151 is parallel to the X axis direction. As shown in FIG. 5, the second portion 152 may be sandwiched between two first portions 151 in the X axis direction. The second portion 152 may be provided above the temperature detecting element 178. Any of the first portions 151 may be provided to extend toward the second electrode 50-2 (for example, the gate pad).

When the protective film 150-1 has the first portion 151 and the second portion 152, the width and the length of the first portion 151 may be applied to the width W1 and the length L1 described above. In the present example, a width of the second portion 152 in the Y axis direction is denoted as W2, and a length in the X axis direction is denoted as L2. The energy to eject the excessive portion 162 inside the solder tunnel 170 to the outside is considered to be the energy of the air inside the solder tunnel 170 to expel the excessive portion 162. Pressure loss Δh (m) of the air inside the solder tunnel 170 is expressed in the Darcy-Weisbach equation below.

$$Δ h = ( λ \times L \times {v}^{2} ) / ( D \times ( 2 g ) ) \qquad Equation 1$$

Note that, λ is a friction coefficient of the solder tunnel 170, L is a length (m) of the solder tunnel 170, v is a flow velocity (m/s) of the air inside the solder tunnel 170, D is an inside diameter (m) of the solder tunnel 170, and g is an acceleration of gravity (m/s²).

As shown in Equation 1, the energy to be applied to the excessive portion 162 depends on λ, L, and D. In the present specification, scatter index I (μm) in the following equation is used as an index to represent the energy to be applied to the excessive portion 162.

$$I = λ \times L / D \qquad Equation 2$$

The protective film 150-1 and the solder portion 160 are exposed to the inner wall of the solder tunnel 170. A friction coefficient of the protective film 150-1 formed of resin or the like is sufficiently higher than a friction coefficient of the solder portion 160 and the leadframe 130 formed of metal, and thus the friction coefficient of the solder tunnel 170 can be approximated using the friction coefficient of the protective film 150-1. In the present specification, an arithmetic average roughness Ra (μm) on the surface of the protective film 150-1 is used as a coefficient to represent the friction coefficient of the protective film 150-1. The smaller the arithmetic average roughness Ra is, the smoother the surface of the protective film 150-1 is, and the friction coefficient becomes smaller. Since the protective film 150-1 is exposed only to the bottom surface of the solder tunnel 170 and not exposed to the two side surfaces and the upper surface, Ra/4 is used as the friction coefficient λ of the solder tunnel 170. In addition, the length L1 of the protective film 150-1 arranged below the leadframe 130 corresponds to the length L of the solder tunnel 170.

The height of the solder tunnel 170 is considered to depend on the width W1 of the protective film 150-1. That is, the wider the width W1 is, the higher the solder tunnel 170 becomes. In the present specification, the following equation is used as an equation to represent the inside diameter D of the solder tunnel 170.

$$D = 2 \times {( W 1 \times W 1 / π )}^{0.5} \qquad Equation 3$$

When λ=Ra/4, L=L1, and D=(W1×W1/n)^{0.5} are substituted into Equation 2, the scatter index I is as indicated in the following equation.

$$I = ( ( Ra / 4 ) \times L 1 ) / ( 2 \times {( W 1 \times W 1 / π )}^{0.5} ) \qquad Equation 4$$

The scatter index I indicates the energy to be applied to the excessive portion 162. That is, the scatter index I indicates the flying distance of the ejected excessive portion 162 from the end 175 of the solder tunnel 170. The higher the scatter index I is, the larger the energy to be applied to the excessive portion 162 is, and the flying distance also increases.

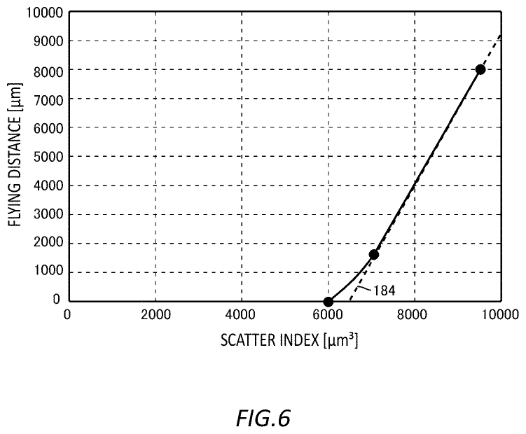

FIG. 6 shows a measurement result of a relationship between the scatter index I and an excessive portion 162. In the present example, the solder used for the solder portion 160 is Sn—Cu based solder, with a specific gravity of about 7.3 g/cm³. In addition, the width W2 of the second portion 152 is equal to or more than three times the width W1. The length L2 of the second portion 152 is equal to or more than 0.7 times and equal to or less than 1.3 times the length L1. Since the width W 2 of the second portion 152 is sufficiently wider than W1, the energy to be applied to the excessive portion 162 can be approximated using the energy in the first portion 151.

As shown in FIG. 6, it can be seen that the higher the scatter index I is, the larger the flying distance of the excessive portion 162 becomes. Thus, the flying distance of the excessive portion 162 can be estimated by the scatter index I. When the relationship between the scatter index I and the flying distance FD (μm) shown in FIG. 6 is approximated using a straight line 184, the following equation is obtained.

$$F D = 2.583 \times I - 16599 \qquad Equation 5$$

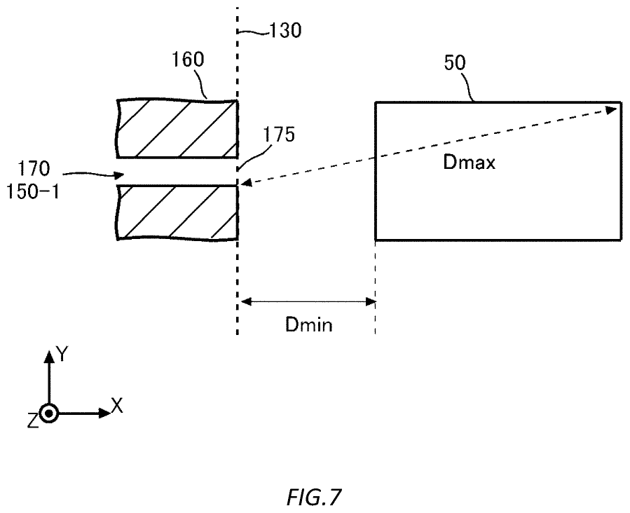

FIG. 7 shows an arrangement example of an end 175 of the protective film 150-1 and a second electrode 50. As described above, the end 175 of the protective film 150-1 is also the end of the solder tunnel 170. The shortest distance between the end 175 of the protective film 150-1 and the second electrode 50 is denoted as Dmin (μm). If the flying distance FD indicated by Equation 5 is smaller than said shortest distance (Dmin), it is possible to inhibit the excessive portion 162 from scattering on the second electrode 50. That is, the scatter index I needs to satisfy the following equation.

$$D min > 2.583 \times I - 16599 \qquad Equation 6$$

The scatter index I may need to satisfy the following equation.

$$0.8 \times D min > 2.583 \times I - 16599 \qquad Equation 7$$

In this case, it is possible to further inhibit the excessive portion 162 from scattering on the second electrode 50.

The scatter index I may be equal to or less than 6000. As shown in FIG. 6, when the scatter index I is equal to or less than 6000, the flying distance of the excessive portion 162 becomes zero. Thus, it is possible to further inhibit the excessive portion 162 from scattering on the second electrode 50.

The wider the width W1 of the protective film 150-1 is, the smaller the scatter index I can be. The width W1 may be 0.15 mm or more, 0.2 mm or more, 0.3 mm or more, 0.5 mm or more, or 0.7 mm or more. The width W1 may be equal to or more than 0.5 times or 0.75 times the width W2. The width W1 may be wider than the width W2. In addition, a width at the end 175 in the Y axis direction may be wider than a width of any other portion in the Y axis direction. The width of the protective film 150-1 may become wider toward the end 175 in a tapered manner or in a stepped manner. In this case, the width of the end 175 may be narrower than, equal to, or wider than the width W2.

The shorter the length L1 of the protective film 150-1 is, the smaller the scatter index I can be. The length L1 may be 3 mm or less, 2 mm or less, or 1.5 mm or less. The length L1 may be equal to or less than 1.3 times the length L2, may be shorter than the length L2, or may be equal to or less than 0.5 times the length L2.

The smaller the arithmetic average roughness Ra of the surface of the protective film 150-1 is, the smaller the scatter index I can be. The arithmetic average roughness Ra may be 2500 μm or less, 2000 μm or less, 1500 μm or less, or 1000 μm or less.

The maximum distance between the end 175 of the protective film 150-1 and the second electrode 50 is denoted as Dmax (μm). The maximum distance Dmax may be the maximum distance in the X axis direction in which the protective film 150-1 extends, or may be the maximum distance in all directions. If the flying distance FD indicated in Equation 5 is larger than the maximum distance Dmax, the excessive portion 162 scatters leaping over the second electrode 50, and thus it is possible to inhibit the excessive portion 162 from adhering to the second electrode 50. That is, the scatter index I needs to satisfy the following equation.

$$D max < 2.583 \times I - 16599 \qquad Equation 8$$

The scatter index I may need to satisfy the following equation.

$$1.2 \times D max < 2.583 \times I - 16599 \qquad Equation 9$$

In this case, it is possible to further inhibit the excessive portion 162 from scattering on the second electrode 50.

The narrower the width W1 of the protective film 150-1 is, the larger the scatter index I can be. The width W1 may be 0.1 mm or less, 0.075 mm or less, or 0.05 mm or less. The width W1 may be equal to or less than 0.5 times, 0.3 times, or 0.1 times the width W2. In addition, the width of the protective film 150-1 may become narrower toward the end 175 in a tapered manner or in a stepped manner.

The longer the length L1 of the protective film 150-1 is, the larger the scatter index I can be. The length L1 may be 5 mm or more, 6 mm or more, or 7 mm or more. The length L1 may be equal to or more than 1.5 times the length L2 or may be equal to or more than 1.7 times the length L2.

The larger the arithmetic average roughness Ra of the surface of the protective film 150-1 is, the larger the scatter index I can be. The arithmetic average roughness Ra may be 3000 μm or more, 3500 μm or more, 4000 μm or more, or 5000 μm or more.

When the protective film 150-1 has a plurality of first portions 151, at least one first portion 151 may satisfy any of the conditions of the scatter index I described above. As an example, among the plurality of first portions 151, the first portion 151 that has the end 175 closest to the gate pad (for example, the second electrode 50-2) may satisfy the conditions of the scatter index I described above. In another example, all of the first portions 151 may satisfy any of the conditions of the scatter index I described above. Any one of the first portions 151 may satisfy the condition of Equation 6 or Equation 7, and another any one of the first portion 151 may satisfy the condition of Equation 8 or Equation 9.

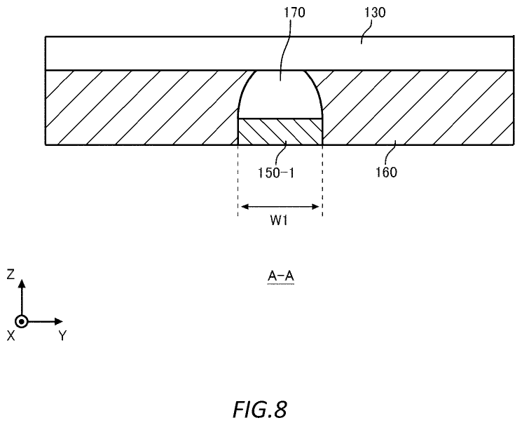

FIG. 8 shows another example of the A-A cross section. In the example of FIG. 4, a space (solder tunnel 170) is formed above the protective film 150-1, and the solder portion 160 is provided between the space and the leadframe 130. That is, the leadframe 130 is not exposed to the solder tunnel 170. In the example of FIG. 8, there is a region in which no solder portion 160 is provided between the space (solder tunnel 170) above the protective film 150-1 and the leadframe 130. That is, the bottom surface of the leadframe 130 is exposed to the solder tunnel 170.

the arithmetic average roughness of the bottom surface of the leadframe 130 exposed to the solder tunnel 170 may be smaller than the arithmetic average roughness Ra of the protective film 150-1. In this case, by the leadframe 130 being exposed to the solder tunnel 170, the friction coefficient in the inner wall of the solder tunnel 170 can be decreased, and the flying distance of the excessive portion 162 can be shorter than the flying distance FD indicated in Equation 5. Accordingly, it is possible to inhibit the excessive portion 162 from reaching the second electrode 50. An area of the bottom surface of the leadframe 130 that is exposed to the solder tunnel 170 may be equal to or more than half or 0.75 times the area of the upper surface of the protective film 150-1, or may be one times or more than one times the area of the upper surface of the protective film 150-1.

Asperities may be formed on the bottom surface of the leadframe 130 exposed to the solder tunnel 170 to increase the arithmetic average roughness of the bottom surface of the leadframe 130 compared to the arithmetic average roughness Ra of the protective film 150-1. By the arithmetic average roughness of the bottom surface of the leadframe 130 being increased, the flying distance of the excessive portion 162 can be longer. Accordingly, the excessive portion 162 can leap over the second electrode 50 more easily. The arithmetic average roughness of the bottom surface of the leadframe 130 may be equal to or more than twice, five times, or ten times the arithmetic average roughness Ra of the protective film 150-1. An area of the bottom surface of the leadframe 130 that is exposed to the solder tunnel 170 may be equal to or more than half or 0.75 times the area of the upper surface of the protective film 150-1, or may be one times or more than one times the area of the upper surface of the protective film 150-1.

While the present invention has been described by way of the embodiments, the technical scope of the present invention is not limited to the above-described embodiments. It is apparent to persons skilled in the art that various alterations or improvements can be made to the above-described embodiments. It is also apparent from description of the claims that the embodiments to which such alterations or improvements are made can be included in the technical scope of the present invention.

What is claimed is:

1. A semiconductor apparatus, comprising:
a semiconductor substrate;
a first electrode arranged above the semiconductor substrate;
a protective film having a portion provided above the first electrode;
a solder portion that is arranged in contact with an upper surface of the first electrode, arranged sandwiching the protective film in a first direction that is parallel to the upper surface, and arranged without sandwiching the protective film in a second direction that is different from the first direction;
a leadframe that is fixed by the solder portion and arranged above the protective film; and
a second electrode that is arranged above the semiconductor substrate on an outer side in the second direction relative to an end, in the second direction, of the protective film arranged below the leadframe, wherein
when a width of the protective film in the first direction arranged below the leadframe is denoted as W1 (μm), a length of the protective film in the second direction is denoted as L1 (μm), an arithmetic average roughness of a surface of the protective film is denoted as Ra (μm), a scatter index is denoted as I, and a shortest distance between the end of the protective film and the second electrode is denoted as Dmin (μm), following equations are satisfied:
$$I = ( ( Ra / 4 ) \times L 1 ) / ( 2 \times {( W 1 \times W 1 / π )}^{0.5} )$$
$$D min > 2.583 \times I - 16599.$$

2. The semiconductor apparatus according to claim 1, wherein
the scatter index satisfies a following equation:
$$0.8 \times D min > 2.583 \times I - 16599.$$

3. The semiconductor apparatus according to claim 1, wherein
the scatter index is 6000 or less.

4. A semiconductor apparatus, comprising:
a semiconductor substrate;
a first electrode arranged above the semiconductor substrate;
a protective film having a portion provided above the first electrode;
a solder portion that is arranged in contact with an upper surface of the first electrode, arranged sandwiching the protective film in a first direction that is parallel to the upper surface, and arranged without sandwiching the protective film in a second direction that is different from the first direction;
a leadframe that is fixed by the solder portion and arranged above the protective film; and
a second electrode that is arranged above the semiconductor substrate on an outer side in the second direction relative to an end, in the second direction, of the protective film arranged below the leadframe, wherein
when a width of the protective film in the first direction arranged below the leadframe is denoted as W1 (μm), a length of the protective film in the second direction is denoted as L1 (μm), an arithmetic average roughness of a surface of the protective film is denoted as Ra (μm), a scatter index is denoted as I, and a maximum distance between the end of the protective film and the second electrode is denoted as Dmax (μm), following equations are satisfied:
$$I = ( ( Ra / 4 ) \times L 1 ) / ( 2 \times {( W 1 \times W 1 / π )}^{0.5} )$$
$$D max < 2.583 \times I - 16599.$$

5. The semiconductor apparatus according to claim 4, wherein
the scatter index satisfies a following equation:
$$1.2 D max < 2.583 \times I - 16599.$$

6. The semiconductor apparatus according to claim 1, wherein the protective film arranged below the leadframe includes:
a second portion; and
a first portion that is provided to extend in a direction toward the second electrode from the second portion and that has a narrower width in the first direction than the second portion, and
a length L1 of the protective film is a length of the first portion in the second direction.

7. The semiconductor apparatus according to claim 2, wherein
the protective film arranged below the leadframe includes:
a second portion; and
a first portion that is provided to extend in a direction toward the second electrode from the second portion and that has a narrower width in the first direction than the second portion, and
a length L1 of the protective film is a length of the first portion in the second direction.

8. The semiconductor apparatus according to claim 3, wherein
the protective film arranged below the leadframe includes:
a second portion; and
a first portion that is provided to extend in a direction toward the second electrode from the second portion and that has a narrower width in the first direction than the second portion, and
a length L1 of the protective film is a length of the first portion in the second direction.

9. The semiconductor apparatus according to claim 4, wherein
the protective film arranged below the leadframe includes:
a second portion; and
a first portion that is provided to extend in a direction toward the second electrode from the second portion and that has a narrower width in the first direction than the second portion, and
a length L1 of the protective film is a length of the first portion in the second direction.

10. The semiconductor apparatus according to claim 5, wherein
the protective film arranged below the leadframe includes:
a second portion; and
a first portion that is provided to extend in a direction toward the second electrode from the second portion and that has a narrower width in the first direction than the second portion, and
a length L1 of the protective film is a length of the first portion in the second direction.

11. The semiconductor apparatus according to claim 1, wherein
a space is formed above the protective film arranged below the leadframe, and the solder portion is provided between the space and the leadframe.

12. The semiconductor apparatus according to claim 2, wherein
a space is formed above the protective film arranged below the leadframe, and the solder portion is provided between the space and the leadframe.

13. The semiconductor apparatus according to claim 3, wherein
a space is formed above the protective film arranged below the leadframe, and the solder portion is provided between the space and the leadframe.

14. The semiconductor apparatus according to claim 4, wherein
a space is formed above the protective film arranged below the leadframe, and the solder portion is provided between the space and the leadframe.

15. The semiconductor apparatus according to claim 5, wherein
a space is formed above the protective film arranged below the leadframe, and the solder portion is provided between the space and the leadframe.

16. The semiconductor apparatus according to claim 1, wherein
a space is formed above the protective film arranged below the leadframe, and there is a region in which the solder portion is not provided between the space and the leadframe.

17. The semiconductor apparatus according to claim 2, wherein
a space is formed above the protective film arranged below the leadframe, and there is a region in which the solder portion is not provided between the space and the leadframe.

18. The semiconductor apparatus according to claim 3, wherein
a space is formed above the protective film arranged below the leadframe, and there is a region in which the solder portion is not provided between the space and the leadframe.

19. The semiconductor apparatus according to claim 4, wherein
a space is formed above the protective film arranged below the leadframe, and there is a region in which the solder portion is not provided between the space and the leadframe.

20. The semiconductor apparatus according to claim 5, wherein
a space is formed above the protective film arranged below the leadframe, and there is a region in which the solder portion is not provided between the space and the leadframe.
